(19) United States
(12) Patent Application Publication
(10) Pub. No.: US 2020/0221606 A1
(43) Pub. Date: Jul. 9, 2020

(54) METHOD OF MANUFACTURING SUS INTEGRAL THIN FILM PLATE TYPE HEAT PIPE FOR SMARTPHONE FRAME

(71) Applicant: POLAR&Co., INC., Gunpo-si (KR)

(72) Inventors: Kiwoo LEE, Daejeon (KR); Jongsun KIM, Hwaseong-si (KR); Sanggyung KIM, Suwon-si (KR); Jinglong CUI, Shenzhen city (CN)

(21) Appl. No.: 16/577,293

(22) Filed: Sep. 20, 2019

(30) Foreign Application Priority Data
Jan. 7, 2019 (KR) 10-2019-0001633

(51) Int. Cl. H05K 7/20; F28D 15/02

(52) U.S. Cl. CPC H05K 7/20336; F28D 15/02

(57) ABSTRACT

Provided is a method of manufacturing a stainless steel (SUS) integral thin film plate type heat pipe for a smartphone frame, and more specifically, a method of manufacturing an SUS integral thin film plate type heat pipe for a smartphone frame, which is formed by coupling an upper plate and a lower plate, has an accommodation space for a working fluid formed therein, allows the working fluid to be evaporated and condensed to cool a heating unit of a smartphone, and includes various wicks formed on the upper and lower plates so that the working fluid is smoothly moved. In addition, the heat pipe may be used to be integrated into a frame of a smartphone through insert injection and may implement a frame and a cooling device of the smartphone at the same time without an increase in thickness.

### BACKGROUND

### 1. Field of the Invention

Embodiments of the inventive concept relate to a method of manufacturing a stainless steel (SUS) integral thin film plate type heat pipe for a smartphone frame used to be integrated into a frame of a smartphone, in which an accommodation space in a vacuum state is formed in a heat pipe in a vacuum state, a working fluid in the accommodation space is heated by an external heat source to generate vapor, the vapor is moved and cooled to become a condensate in an upper plate of the heat pipe, and a lower plate allows the cooled condensate to be moved back to a heating unit at one side, thereby radiating heat generated in a smartphone.

### 2. Discussion of Related Art

Describing basic structures of smartphones, current smartphones have a structure in which a frame structure made of stainless steel, magnesium, or aluminum is provided inside the smartphone, a display is mounted at a front side of the frame, and a driving circuit and a battery are mounted at a rear side of the frame.

In the smartphones, since a processing speed of a central processing unit (CPU) is fast and the CPU performs various steps, an operation amount of the CPU is increased, and thus, heat generated in the CPU is increased. Moreover, due to a slim structure of the smartphones, it is not easy to install an effective cooling unit in the smartphones.

Therefore, high heat is generated in the smartphones, and excessive heat generated in the smartphones causes discomfort and anxiety to a user. That is, since it has been reported that the smartphones have been exploded due to battery fault or the like, when the smartphones become too hot, a user may be in great anxiety. Aside from the explosion, heat generated in the smartphones may cause operation errors, and thus, it is necessary to radiate heat and cool the heat as quickly as possible.

Conventionally, heat generated in a CPU and a battery inside a smartphone has been reduced using a heat radiator having a heat pipe structure. However, when the conventional heat pipe is used, there is a problem in that cooling efficiency is low.

More specifically, when a heat plate made of copper is used, an inner thickness is increased by 0.4 mm. In addition, a copper material is too soft, and thus, the heat plate is easily damaged by slight impact or contact. Furthermore, the heat plate is bonded to a frame inside the smartphone through double-sided bonding, and thus, heat resistance is generated, which adversely affects radiation of heat.

Accordingly, there is a need to manufacture and develop a heat pipe usable in a smartphone, which is capable of solving such problems.

### SUMMARY OF THE INVENTION

Embodiments of the inventive concept provide a method of manufacturing a plate type heat pipe, which is capable of sufficiently solving a heating problem of a recent smartphone (or a 5G or game phone) and by which a thin film plate type heat pipe including an upper plate and a lower plate is manufactured, an accommodation space for a working fluid configured to radiate heat (cooling) is formed at a position desired by a user, the working fluid in the accommodation space is allowed to be repeatedly circulated such that the working fluid absorbs heat of a heating unit to become vapor, is moved to a side opposite to the heating unit to be cooled, and then is moved back to the heating unit, and wicks having various shapes are implemented in the upper and lower plates such that the vapor and condensate of the working fluid is smoothly moved, thereby increasing heat radiation efficiency.

In addition, embodiments of the inventive concept provide a method of manufacturing a stainless steel (SUS) integral thin film plate type heat pipe for a smartphone frame, which is implemented to have a thickness corresponding to the form of a thin film plate and is manufactured to have a structure integrated with a frame of a smartphone, thereby performing two functions of a frame and a cooling device of the smartphone without an increase in thickness.

Other objects and advantages of the present inventive concept will be explained below and understood from embodiments of the present inventive concept. In addition, the objects and advantages of the present inventive concept may be realized by components and combinations thereof defined in the appended claims.

In accordance with an aspect of the inventive concept, a method of manufacturing an SUS integral thin film plate type heat pipe for a smartphone frame includes step S100 which provides providing a heat pipe (100) made of SUS formed by coupling a lower plate (10) and an upper plate (20), wherein the lower plate (10) has an accommodation space (S) for a working fluid formed therein and includes a first wick (12) formed on an upper surface thereof in which the working fluid is heated at one side thereof and rises in a state of vapor, and the upper plate (20) allows the vapor to be repeatedly circulated such that the vapor is moved in a lengthwise direction thereof through a second wick (22) formed on an inner lower surface thereof, is condensed to drop to the lower plate (10), and then is moved toward a space in which a heating unit is located by the first wick (12) of the lower plate (10), step S300 which provides filling the working fluid in the heat pipe (100), step S400 which provides freezing the working fluid in the heat pipe (100); step S500 which provides vacuuming process inside the heat pipe (100); and step S800 which provides performing insert injection to form an edge (60) with a preset shape and size on an outer peripheral surface of the heat pipe (100) to manufacture an integral thin film plate type heat pipe (200) for a smartphone frame.

### BRIEF DESCRIPTION OF THE DRAWINGS

FIG. 1 is a view illustrating an example of a method of manufacturing a stainless steel (SUS) integral thin film plate type heat pipe for a smartphone frame according to a first embodiment of the present inventive concept (a case in which a wick of a second case is applied to each of a first accommodation portion and an upper plate).

FIG. 2 is a view illustrating an example of the method of manufacturing the SUS integral thin film plate type heat pipe for the smartphone frame according to the first embodiment of the present inventive concept (a case in which a wick of a first case is applied to a first accommodation portion and a wick of a fifth case is applied to a second accommodation portion).

FIG. 3 is a view illustrating an example of the method of manufacturing the SUS integral thin film plate type heat pipe for the smartphone frame according to the first embodiment of the present inventive concept (a case in which the wick of the second case is applied to each of first and second accommodation portions and a shape of an upper plate is different from that of FIG. 1).

FIG. 4 is a view illustrating an example of the method of manufacturing the SUS integral thin film plate type heat pipe for the smartphone frame according to the first embodiment of the present inventive concept (a case in which a wick of a sixth case is applied to a first accommodation portion and a wick of a first case is applied to a second accommodation portion).

FIG. 5 is a set of views illustrating examples of shapes of wicks formed on an upper plate and a lower plate according to the present inventive concept.

FIG. 6 is a view illustrating an example of a flow of an internal working fluid in the SUS integral thin film plate type heat pipe for the smartphone frame manufactured according to the method of the present inventive concept.

FIG. 7 is a view illustrating a structure of a conventional smartphone.

FIG. 8 is a process diagram illustrating an example of a sequence of the method of manufacturing the SUS integral thin film plate type heat pipe for the smartphone frame according to the present inventive concept.

FIG. 9 is a set of views illustrating examples of insert-injecting a heat pipe and an edge according to an embodiment of the present inventive concept.

FIG. 10 is a set of views illustrating examples of groove shapes of first and second wicks according to the present inventive concept.

### DETAILED DESCRIPTION OF EXEMPLARY EMBODIMENTS

Before describing various embodiments of the present inventive concept in detail, it is to be understood that the present inventive concept is not limited in its application to the details of configurations and arrangements of components set forth in the following detailed description or drawings. The present inventive concept is capable of being implemented in other embodiments and of being practiced and carried out in various ways. Also, it is to be understood that phraseology and terminology used herein with reference to device or element orientation (such as, for example, terms like “front,” “back,” “up,”, “down,” “top,” “bottom,” “left,” “right,” “lateral,” and the like) are only used to simplify description of the present inventive concept, and do not alone indicate or imply that the device or element referred to must have a particular orientation. In addition, terms such as “first” and “second” are used in the present specification and the appended claims for the purpose of description and are not intended to indicate or imply relative importance or purpose.

The present inventive concept has the following features in order to achieve the above object.

Hereinafter, exemplary embodiments of the present inventive concept will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present inventive concept on the basis of the principle that the inventor is allowed to define terms appropriately for the best explanation.

Therefore, the embodiments disclosed in the present specification and the configurations illustrated in the drawings are merely the most exemplary embodiments of the present inventive concept, and do not represent all of the technical ideas of the present inventive concept, and thus it should be understood that there may be various equivalents and modified examples that could substitute therefor at the time of filing the present application.

Describing an embodiment of the present inventive concept, a method of manufacturing a stainless steel (SUS) integral thin film plate type heat pipe for a smartphone frame includes providing a heat pipe 100 made of SUS formed by coupling a lower plate 10 and an upper plate 20, wherein the lower plate 10 has an accommodation space S for a working fluid formed therein and includes a first wick 12 formed on an upper surface thereof in which the working fluid is heated at one side thereof and rises in a state of vapor, and the upper plate 20 allows the vapor to be repeatedly circulated such that the vapor is moved in a lengthwise direction thereof through a second wick 22 formed on an inner lower surface thereof, is condensed to drop to the lower plate 10, and then is moved toward a space in which a heating unit is located by the first wick 12 of the lower plate 10 (S100); filling the working fluid in the heat pipe 100 (S300); freezing the working fluid in the heat pipe 100 (S400); vacuum-processing inside the heat pipe 100 (S500); and performing insert injection to form an edge 60 with a preset shape and size on an outer peripheral surface of the heat pipe 100 to manufacture an integral thin film plate type heat pipe 200 for a smartphone frame (S800).

In addition, step S100 includes providing the lower plate 10 with a preset width and thickness such that a first accommodation portion 11 with a preset shape is locally formed at a preset portion of the upper surface thereof (S110); providing the upper plate 20 with a size and a shape corresponding to the first accommodation portion 11 (S111); fitting a brazing adhesive layer 30 to the edge 60 of the first accommodation portion 11 or silk-printing an adhesive on the edge 60 to couple the upper plate 20 and the lower plate 10 (S112); and performing a brazing process in a vacuum brazing furnace (S113).

Furthermore, step S100 includes providing the lower plate 10 with a preset width and thickness such that a first accommodation portion 11 with a preset shape is locally formed at a preset portion of the upper surface thereof (S120); providing the upper plate 20 with a preset width and thickness to have the same shape as the lower plate 10 such that a second accommodation portion 21 with a preset shape is locally formed at a preset portion of the lower surface thereof (S121); fitting a brazing adhesive layer 30 to the edge 60 of the first or second accommodation portion 11 or 21 in a manner such that the first or second accommodation portion 11 or 21 is correspondingly coupled to the upper plate 20 (S122); and performing a brazing process in a preset temperature range in a vacuum brazing furnace (S123).

In addition, in step S800, among a first shape in which a plurality of fixing holes 110 are formed to be spaced apart from each other, a second shape in which a plurality of fixing protrusions 120 are formed to be spaced apart from each other, and a third shape in which fixing band portions 130 extending in a direction orthogonal to one surface of the heat pipe 100 are locally formed, one is formed at a periphery of the heat pipe 100 at which the upper plate 20 and the lower plate 10 are coupled so that a fastening and fixing force is increased between the edge 60 and the heat pipe 100 during insert injection.

Furthermore, the first wick 12 and the second wick 22 are characterized by combining two cases so as to correspond to each other, wherein the two cases are selected from a second case of a groove shape in which a plurality of first recess lines 13 are consecutively formed in a lengthwise direction, a first case of a dot shape in which a plurality of protrusions are formed, a third case of a groove-dot shape in which the first recess lines 13 and the protrusions are alternately and consecutively formed in a width direction, and a fourth case in which a sintered metal wick is formed.

In addition, the first wick 12 or the second wick 22 is formed as any one of a fifth case in which a mesh wick 15 is correspondingly coupled and a sixth case in which the mesh wick 15 is correspondingly coupled to a surface in which the second case of the groove shape is formed.

Furthermore, in the second case of the groove shape, a second recess line 16 is formed at one side in contact with the heating unit in a width direction orthogonal to the first recess line 13 formed in the lengthwise direction of the upper plate and the lower plate, and both ends of the second recess line 16 are connected to or disconnected from the first recess line 13.

In addition, the first accommodation portion 11 recessed in the upper surface of the lower plate 10 and the second accommodation portion 21 recessed in the lower surface of the upper plate 20 are formed through corrosion processing.

The method is usable to manufacture a frame of a portable game machine or a wireless charger.

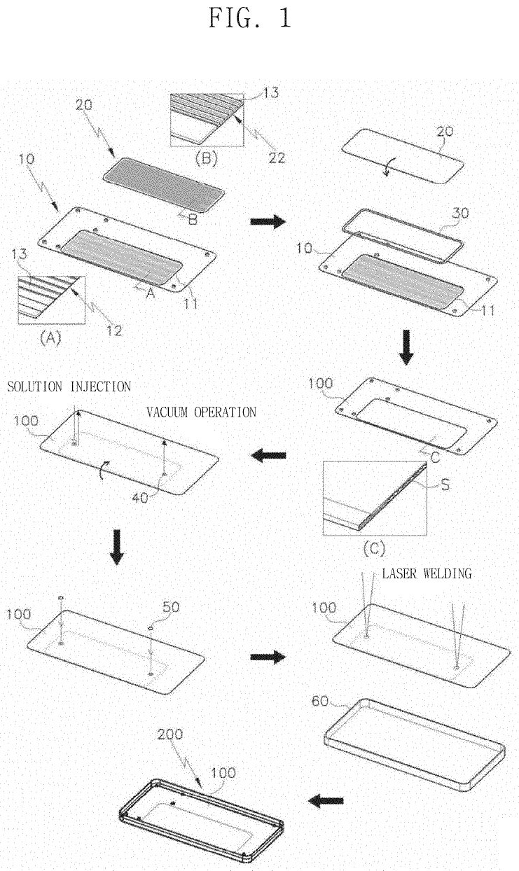

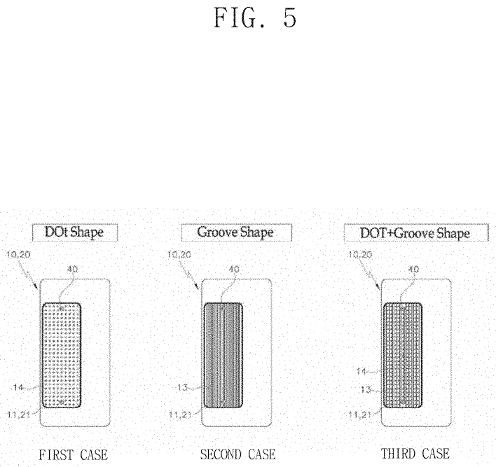

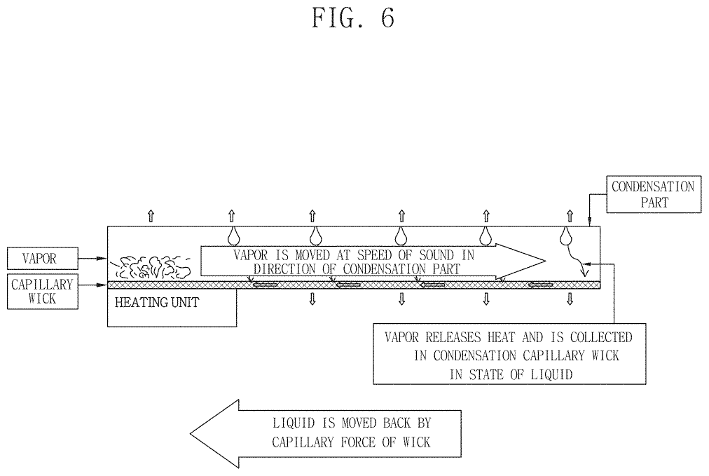

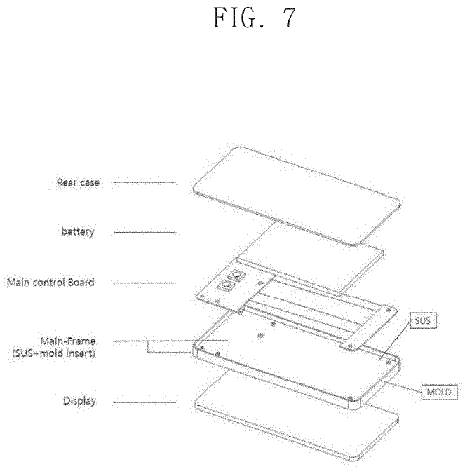

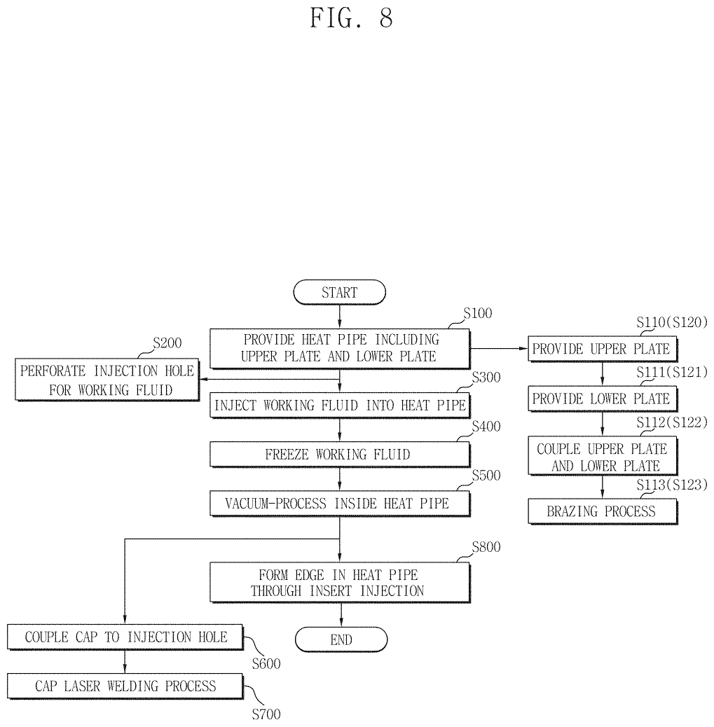

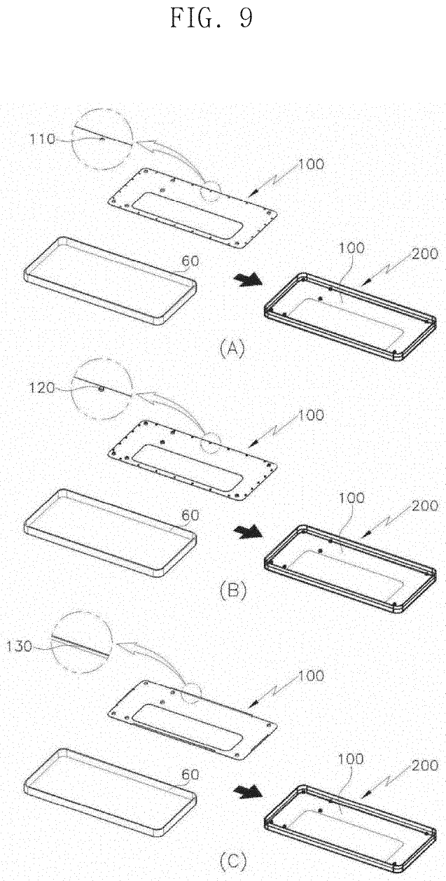

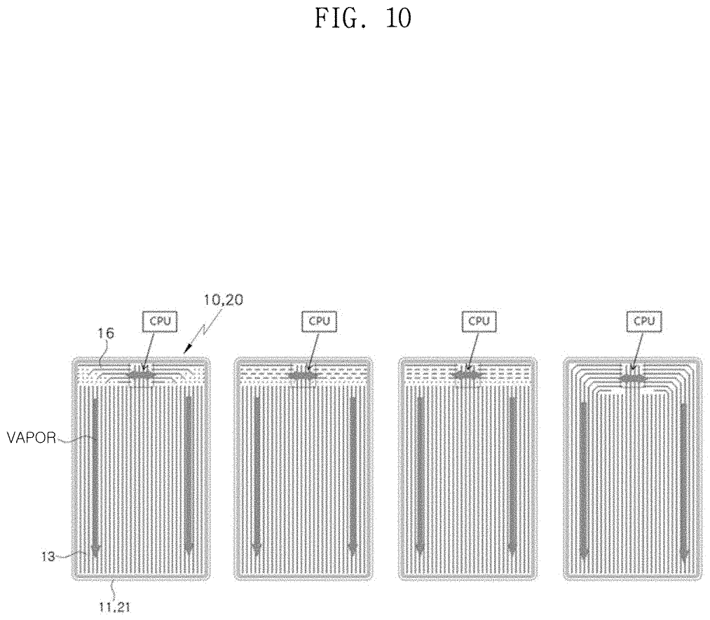

Hereinafter, a method of manufacturing an SUS integral thin film plate type heat pipe for a smartphone frame will be described in detail with reference to FIGS. 1 to 10.

A conventional smartphone frame is made of a SUS plate having a thickness of 0.3 mm to 0.5 mm and is manufactured by performing a press processing process and then performing an insert-mold injection molding process. In the method of manufacturing the SUS integral thin film plate type heat pipe for the smartphone frame according to the present inventive concept, an integral heat pipe for a smartphone frame is manufactured by adding a process of the heat pipe 100 to the processes.

A manufacturing process of the heat pipe 100 is as follows.

1. The heat pipe 100 made of SUS is manufactured by coupling a lower plate 10 and an upper plate 20, wherein the lower plate 10 has an accommodation space S for a working fluid formed therein in which the working fluid is heated at one side thereof by a heating unit and rises in a state of vapor, and the upper plate 20 allows the vapor to be repeatedly circulated such that the vapor is moved in a lengthwise direction thereof through a second wick 22 formed on an inner lower surface thereof, is condensed to drop to the lower plate 10, and then is moved toward a space of the heating unit (such as a main control board, a battery, or the like disposed at a position of a smartphone in close contact with one side of one surface of the heat pipe of the present inventive concept to generate heat) by a first wick 12 of the upper surface of the lower plate 10 (S100). In the heat pipe 100 (vapor chamber) of the present inventive concept, the upper plate 20 and the lower plate 10 are integrally formed to form the accommodation space S for the working fluid, which is in a vacuum state, and wicks for a smooth movement of the working fluid (such as a refrigerant) according to various embodiments are formed in the accommodation space S.

First, according to embodiments, there are two embodiments that have a first embodiment in which the upper plate 20 and the lower plate 10 have different shapes and a second embodiment in which the upper plate 20 and the lower plate 10 have the same shape.

The first embodiment includes providing the lower plate 10 with a preset width and thickness (for example, 0.3 mm to 0.5 mm) such that a first accommodation portion 11 with a preset shape (for example, a circular shape, a polygonal shape, or the like) is locally formed at a preset portion of an upper surface thereof (S110); providing the upper plate 20 with a size and a shape corresponding to the first accommodation portion 11 (S111); fitting a brazing adhesive layer 30 to the edge 60 of the first accommodation portion 11 or silk-printing an adhesive on the edge 60 to couple the upper plate 20 and the lower plate 10 (S112); and performing a brazing process in a preset temperature range (medium temperature of 700° C. to 800° C. or high temperature of 1,000° C.) in a vacuum brazing furnace (S113).

That is, the first accommodation portion 11 is freely formed at a required position in the lower plate 10 (board) having a total thickness of 0.3 mm to 0.5 mm. A groove of the first accommodation portion 11 is formed to have a desired shape and size at a desired position in the upper surface of the lower plate 10 desired by a user. The upper plate 20 disposed on the upper surface of the lower plate 10 is formed to have a size and shape identical and corresponding to those of the first accommodation portion 11 rather than the same size as the lower plate 10. Thus, the upper plate 20 forms the accommodation space S in the heat pipe 100 formed by coupling the lower plate 10 and the upper plate 20 to each other.

The second embodiment includes providing the lower plate 10 with a preset width and thickness (0.15 mm to 0.25 mm) such that a first accommodation portion 11 with a preset shape is locally formed at a preset portion of an upper surface thereof (S120); providing the upper plate 20 with a preset width and thickness (0.15 mm to 0.25 mm) to have the same shape as the lower plate 10 such that a second accommodation portion 21 with a preset shape is locally formed at a preset portion of a lower surface thereof (S121); fitting a brazing adhesive layer 30 to an edge 60 of the first or second accommodation portion 11 or 21 in a manner such that the first or second accommodation portion 11 or 21 is correspondingly coupled to the upper plate 20 (S122); and performing a brazing process in a preset temperature range in a vacuum brazing furnace (S123).

Unlike the above-described first embodiment, two plates of the upper plate 20 and the lower plate 10 (board) having the same or a similar thickness are superimposed and welded to manufacture a SUS frame integral heat pipe 200 having a thickness of 0.3 mm to 0.5 mm. The lower plate 10 and the upper plate 20 have the same size and shape. The first accommodation portion 11 and the second accommodation portion 21 having the same shape and size are recessed and formed in the upper surface of the lower plate 10 and the lower surface of the upper plate 20 coupled to an upper portion of the lower plate 10, respectively, and thus, the accommodation space S is formed in the heat pipe 100 formed by coupling the lower plate 10 and the upper plate 20.

In addition, in the present inventive concept, although the first and second accommodation portions 11 and 21 are formed through corrosion processing, various methods may replace the corrosion processing as long as the methods are for forming the first and second accommodation portions 11 and 21.

Furthermore, in order to smoothly move the working fluid in one direction from one side to the other side or from the other side to one side, a first wick 12 and a second wick 22 having various shapes are respectively formed in the lower plate 10 and the upper plate 20 as manufactured above. Embodiments of the first wick 12 and the second wick 22 are as follows.

The first wick 12 formed in the first accommodation portion 11 of the lower plate 10 allows a condensate to be smoothly moved to a space in which a heating unit is located at one side by a capillary force. The second wick 22 is also formed in the second accommodation portion 21 of the upper plate 20 and allows a condensate or vapor to be smoothly moved.

In addition, the first wick 12 and the second wick 22 are formed by combining two cases so as to correspond to each other, wherein the two cases are selected from

1) a second case of a groove shape in which a plurality of first recess lines 13 are consecutively formed in a lengthwise direction, 2) a first case of a dot shape (14) in which a plurality of protrusions are formed, 3) a third case of a groove-dot mixture shape in which the first recess lines 13 and the protrusions are alternately and consecutively formed in a width direction, 4) a fourth case in which a sintered metal wick is formed, 5) a fifth case in which the mesh wick 15 is correspondingly coupled, and 6) a sixth case in which the mesh wick 15 is correspondingly coupled to an upper surface in which the second case of the groove shape is formed.

Furthermore, in the second case of the groove shape, second recess lines 16 are formed at one side in contact with a heating unit (for example, a central processing unit (CPU) or the like) in a width direction orthogonal to the first recess lines 13 formed in the lengthwise direction of the upper plate and the lower plate. The second recess line 16 may be formed such that both ends thereof are connected to or disconnected from the first recess line 13.

That is, in the present inventive concept, according to various embodiments of a user, of course, wicks of six cases which are formed in the first accommodation portion 11 on the upper surface of the lower plate 10 and wicks of six cases which are formed in the second accommodation portion 21 on the lower surface of the upper plate 20 may be variously combined and used, and there is no limitation on the combination.

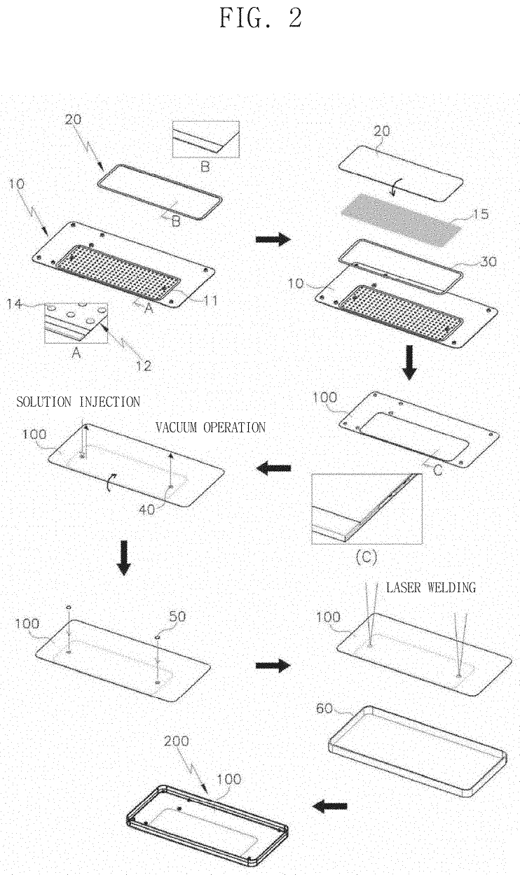

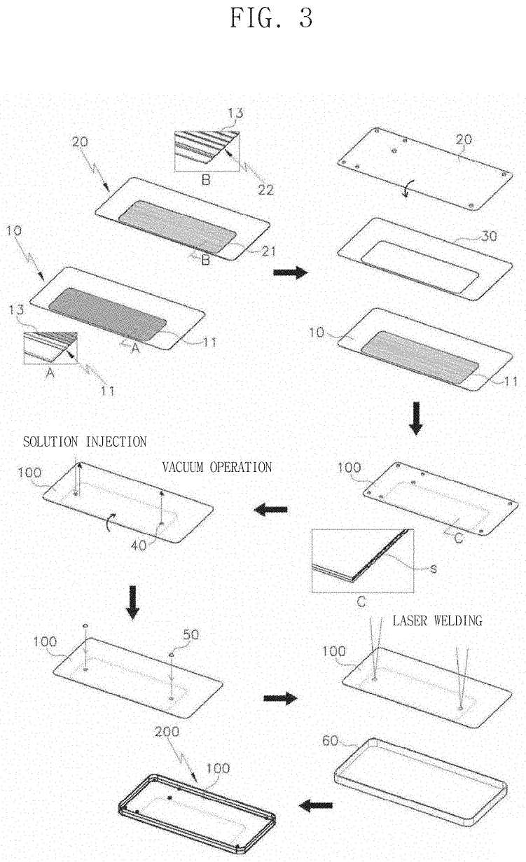

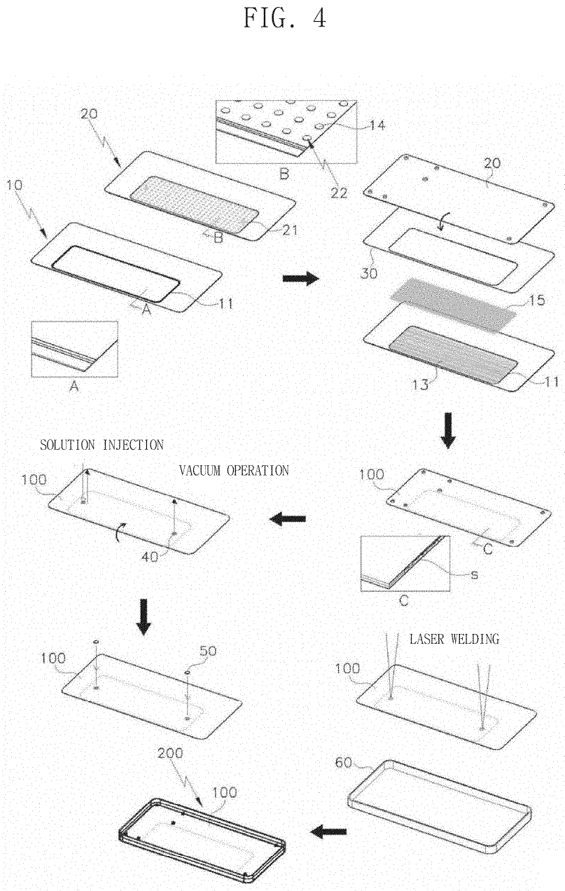

In an embodiment, FIG. 1 illustrates a case in which the wick of the first case is applied to each of the first accommodation portion 11 and the upper plate 20. FIG. 2 illustrates a case in which the wick of the first case is applied to the first accommodation portion 11 and the wick of the fifth case is applied to the second accommodation portion 21. FIG. 3 illustrates a case in which the wick of the second case is applied to each of the first and second accommodation portions 11 and 21 and a shape of the upper plate is different from that of FIG. 1. FIG. 4 illustrates a case in which the wick of the sixth case is applied to the first accommodation portion 11 and the wick of the first case is applied to the second accommodation portion 21.

As a result, a working fluid, which flows from the first accommodation portion 11 to a heating unit at one side, is evaporated due to heat generated by the heating unit (main control board or the like) of a smartphone disposed on a lower surface of the one side (ex: left side) of the lower plate 10, and evaporated vapor is moved at a speed of sound in a direction from one side to the other side (in a direction away from the heating unit) along the second accommodation portion 21 on a lower surface of the upper plate 20. The vapor is condensed by releasing heat to the outside of the upper plate 20 while moving, and a condensate in a liquid state after releasing the heat is collected on an upper surface of the lower plate 10. Then, the condensate on the upper surface of the lower plate 10 is moved back to the hot heating unit by a capillary force through the various first or second wicks 12 or 22 formed on the upper surface of the lower plate 10.

2. After step S100, an injection hole 40 for injecting a working fluid is formed in the heat pipe 100 (S200). When a shape of the heat pipe 100 is manufactured in step S100, two injection holes 40 are formed in both sides of one surface of the heat pipe 100 toward the accommodation space S, in which the working fluid is accommodated, correspondingly formed by the first accommodation portion 11 or the first and second accommodation portions 11 and 21.

3. The working fluid fills the heat pipe 100 (S300). 4. The working fluid is frozen in the heat pipe (S400). 5. The heat pipe 100 is internally vacuum-processed (S500). When step S200 is completed, the working fluid, which is a refrigerant that is set to be used, is injected through one of the two injection holes 40. After the working fluid is frozen in the heat pipe 100 through various parts and methods, the accommodation space S is internally vacuum-processed in a state in which the working fluid is frozen.

6. After step S500, a cap 50 is correspondingly coupled to the injection hole 40 (S600). 7. After step S600, a laser welding is performed on a coupling portion of the heat pipe 100 in the cap 50 (S700). When step S500 is completed, the cap 50 corresponding to each of the two injection holes 40 is inserted to block the two injection holes 40, and then, the coupling portion of the heat pipe 100 in the cap 50 is welded with a laser and is completely sealed.

8. An edge 60 having a preset shape and size is formed on an outer peripheral surface of the heat pipe 100 through insert injection to manufacture an integral thin film plate type heat pipe 200 for a smartphone frame (S800). When the manufacture of the heat pipe 100 is completed in step S700, the heat pipe 100 may serve as a cooling device. As the edge 60 having various shapes and thicknesses preset by a user is formed on the outer peripheral surface edge of the heat pipe 100, the heat pipe 100 is directly used as a main frame of a smartphone and is used as a cooling device at the same time.

To this end, the heat pipe 100 has the outer peripheral surface, on which the edge 60 having the preset shape and size is formed through insert injection, and is manufactured as the integral thin film plate type heat pipe 200 for the smartphone frame.

Of course, in the present inventive concept, the method of manufacturing the heat pipe 200 has been described by exemplifying the heat pipe integrated into a frame of a smartphone. However, according to various embodiments of a user, of course, the method may be used to replace methods of manufacturing various frames such as frames of a portable game machine and a wireless charger and methods of manufacturing various frames usable for both cooling and a frame.

Furthermore, in order to prevent separation of the heat pipe 100 from the edge 60 during insert injection in step S800, among a first shape A in which a plurality of fixing holes 110 are formed to be spaced apart from each other, a second shape B in which a plurality of fixing protrusions 120 are formed to be spaced apart from each other, and a third shape C in which fixing band portions 130 extending in a direction orthogonal to one surface of the heat pipe 100 are locally formed, one is formed at a periphery of the heat pipe 100 at which the upper plate 20 and the lower plate 10 are coupled. Thus, the edge 60 may fill or cover a portion of the fixing hole 110, the fixing protrusion 120, or the fixing band portion 130 during insert injection, thereby increasing a fastening and fixing force between the edge 60 and the heat pipe 100.

As described above, according to the present inventive concept, an integral thin film plate type heat pipe has almost the same effect as that formed of a conventional copper material without lowering cooling performance.

In addition, since a material (SUS) used in the present inventive concept has high hardness, an integral thin film plate type heat pipe can be manufactured integrally with an inner frame of a smartphone.

Furthermore, according to the present inventive concept, an integral thin film plate type heat pipe performs two functions of a smartphone frame and a cooling device at the same time.

In addition, according to the present inventive concept, a thickness, which is most important in a smartphone, can be reduced by 0.3 mm to 0.5 mm.

Furthermore, according to the present inventive concept, due to high hardness, an integral thin film plate type heat pipe is unlikely to be damaged by slight impact or contact.

In addition, according to the present inventive concept, since an integral thin film plate type heat pipe is integrated into a frame, there is no thermal resistance due to assembly.

Although the present inventive concept has been described by the limited exemplary embodiments and drawings as above, the present inventive concept is not limited to the exemplary embodiments and drawings but will be understood by those of ordinary skill in the art that various changes and modifications may be made therein without departing from the spirit and scope of the present inventive concept as defined by the following claims or their equivalents.

What is claimed is:

1. A method of manufacturing a stainless steel (SUS) integral thin film plate type heat pipe for a smartphone frame, the method comprising:
step S100 which provides a heat pipe (100) made of SUS formed by coupling a lower plate (10) and an upper plate (20), wherein the lower plate (10) has an accommodation space (S) for a working fluid formed therein and includes a first wick (12) formed on an upper surface thereof in which the working fluid is heated at one side thereof and rises in a state of vapor, and the upper plate (20) allows the vapor to be repeatedly circulated such that the vapor is moved in a lengthwise direction thereof through a second wick (22) formed on an inner lower surface thereof, is condensed to drop to the lower plate (10), and then is moved toward a space in which a heating unit is located by the first wick (12) of the lower plate (10);
step S300 which provides filling the working fluid in the heat pipe (100);
step S400 which provides freezing the working fluid in the heat pipe (100);
step S500 which provides vacuum-processing inside the heat pipe (100); and
step S800 which provides performing insert injection to form an edge (60) with a preset shape and size on an outer peripheral surface of the heat pipe (100) to manufacture an integral thin film plate type heat pipe (200) for a smartphone frame.

2. The method of claim 1, wherein step S100 includes:
step S110 which provides providing the lower plate (10) with a preset width and thickness so that a first accommodation portion (11) with a preset shape is locally formed at a preset portion of the upper surface;
step S111 which provides providing the upper plate (20) with a size and a shape corresponding to the first accommodation portion (11);
step S112 which provides fitting a brazing adhesive layer (30) to the edge (60) of the first accommodation portion (11) or silk-printing an adhesive on the edge (60) to couple the upper plate (20) and the lower plate (10); and
step S113 which provides performing a brazing process in a vacuum brazing furnace.

3. The method of claim 1, wherein step S100 includes:
step S120 which provides providing the lower plate (10) with a preset width and thickness so that a first accommodation portion (11) with a preset shape is locally formed at a preset portion of the upper surface;
step S121 which provides providing the upper plate (20) with a preset width and thickness to have the same shape as the lower plate (10) so that a second accommodation portion (21) with a preset shape is locally formed at a preset portion of the lower surface;
step S122 which provides fitting a brazing adhesive layer (30) to the edge (60) of each of the first accommodation portion (11) and the second accommodation portion (21) in a manner such that each of the first accommodation portion (11) and the second accommodation portion (21) is correspondingly coupled to the upper plate (20); and
step S123 which provides performing a brazing process in a preset temperature range in a vacuum brazing furnace.

4. The method of claim 1, wherein, in step 800, among a first shape in which a plurality of fixing holes (110) are formed to be spaced apart from each other, a second shape in which a plurality of fixing protrusions (120) are formed to be spaced apart from each other, and a third shape in which fixing band portions (130) extending in a direction orthogonal to one surface of the heat pipe (100) are locally formed, one is formed at a periphery of the heat pipe (100) in which the upper plate (20) and the lower plate (10) are coupled so that a fastening and fixing force is increased between the edge (60) and the heat pipe (100) during insert injection.

5. The method of claim 1, wherein the first wick (12) and the second wick (22) are characterized by combining two cases so as to correspond to each other, wherein the two cases are selected from a second case of a groove shape in which a plurality of first recess lines (13) are consecutively formed in a lengthwise direction, a first case of a dot shape in which a plurality of protrusions are formed, a third case of a groove-dot shape in which the first recess lines (13) and the protrusions are alternately and consecutively formed in a width direction, and a fourth case in which a sintered metal wick is formed.

6. The method of claim 1, wherein the first wick (12) or the second wick (22) is formed as any one of a fifth case in which a mesh wick (15) is correspondingly coupled and a sixth case in which the mesh wick (15) is correspondingly coupled to a surface in which a second case of a groove shape is formed.

7. The method of claim 5, wherein, in the second case of the groove shape, a second recess line (16) is formed at one side in contact with the heating unit in a width direction orthogonal to the first recess line (13) formed in the lengthwise direction of the upper plate and the lower plate, and both ends of the second recess line (16) are connected to or disconnected from the first recess line (13).

8. The method of claim 3, wherein the first accommodation portion (11) recessed in the upper surface of the lower plate (10) and the second accommodation portion (21) recessed in the lower surface of the upper plate (20) are formed through corrosion processing.

9. The method of claim 1, wherein the method is usable to manufacture a frame of a portable game machine or a wireless charger.
